(19) United States
(12) Patent Application Publication
(10) Pub. No.: US 2024/0051271 A1
(43) Pub. Date: Feb. 15, 2024

(54) COMPOSITE PANE WITH IMPROVED COLOR EFFECT

(71) Applicant: SAINT-GOBAIN GLASS FRANCE, COURBEVOIE (FR)

(72) Inventors: Jan HAGEN, BONN (DE); Stephan GIER, BOUS (DE); Marc KOELLING, AACHEN (DE)

(21) Appl. No.: 18/260,298

(22) PCT Filed: Jan. 12, 2022
(86) PCT No.: PCT/EP2022/050546

§ 371 Date: Jul. 3, 2023

(30) Foreign Application Priority Data
Jan. 28, 2021 (EP) 21154014.1

(51) Int. Cl. B32B 17/10; B32B 7/12

(52) U.S. Cl. CPC B32B 17/10449; B32B 7/12; B32B 17/10036; B32B 17/10229; B32B 17/10614; B32B 17/10935; B32B 17/1077; B32B 17/10788; B32B 17/10816; B32B 2264/1021; B32B 2264/2032; B32B 2307/40; B32B 2307/7376

(57) ABSTRACT

A composite pane includes an outer pane and an inner pane that are joined to one another via a thermoplastic intermediate layer, wherein the composite pane has at least one functional film that contains at least one metal layer, and the thermoplastic intermediate layer is formed with at least one thermoplastic film that contains refractive-index-reducing agents and these refractive-index-reducing agents reduce the refractive index of the thermoplastic film by at least 0.05 in the optically visible range between 380 nm and 780 nm.

The invention relates to a composite pane with improved optical properties, in particular an improved color effect in reflection, and a method for producing such a composite pane and use thereof.

Composite glass panes consist of two or more individual panes and are fixedly bonded to one another with one or a plurality of intermediate layers with heat and pressure. The intermediate layers are usually made of thermoplastics such as polyvinyl butyral (PVB) or ethylene vinyl acetate (EVA).

High demands are made on motor vehicle glazing. The following legal regulations apply with regard to the size of the field of vision and the structural stability of the panes:
ECE R 43: “Einheitliche Vorschriften fur die Genehmigung des Sicherheitsglases and der Verbundglaswerkstoffe [Uniform Provisions Concerning the Approval of Safety Glazing and Composite Glazing Materials]” and
Technische Anforderungen an Fahrzeugteile bei der Bauartprüfung [Technical Requirements for Vehicle Parts for Type Testing] § 22 a StVZO [German road vehicle code], “Safety Glass”.

These regulations are usually satisfied by composite glass panes. Until now, thermoplastic films, in particular polyvinyl butyral (PVB) films that have a refractive index that is as close as possible to that of the outer panes and the inner panes used have been used in the production of the composite panes. Usually, the refractive index of the previously used PVB films is approx. 1.48 in the visible range, which is usually specified at a fixed value, for example, at 500 or 550 nm. (D. C. Miller, Optical Engineering 50(1), 013003, 2011).

It is known to provide windshields with transparent, functional films, for example, with electrically conductive coatings. These coatings can act, for example, as IR-reflecting coatings, to reduce the heating of the vehicle interior and to thereby improve thermal comfort. However, the coatings can also perform other functions and, for example, be used as heatable coatings by connecting them to a voltage source such that a current flows through the coating. Suitable coatings contain, for example, conductive, metallic layers based on silver. Since these layers are susceptible to corrosion, it is customary to apply them on the surface of the outer pane or of the inner pane facing the intermediate layer such that they have no contact with the atmosphere. So-called low-E coatings are however also applied to the inner surface of the inner pane. Silver-containing transparent coatings are known, for example, from WO 03/024155, US2007/0082219 A1, US2007/0020465 A1, WO2013/104438, or WO2013/14439.

WO2019/206493 A1 describes a composite pane with an electrically conductive coating and an antireflection coating as a projection surface for a head-up display.

WO2012/052315 describes a transparent composite pane with an electrically heatable coating, in which at least one electrically heatable coating has at least four functional layers arranged one atop another. Each functional layer includes at least one layer of optically highly refractive material with a refractive index ≥2.1. The functional layer has multiple silver-containing layers and matching and smoothing layers arranged therebetween. The transparent pane has total transmittance of >70%.

DE 202019102388 U1 describes a composite pane including a transparent electrically conductive coating, which additionally has a dielectric superlattice. The superlattice is preferably formed from alternatingly arranged layers with different refractive indices and consists of a large number of individual layers, wherein layers with a high refractive index (preferably greater than 1.8 at a wavelength of 550 nm) and layers with a low refractive index (preferably less than 1.8 at a wavelength of 550 nm) are arranged alternatingly one above the other. The superlattice results in a reduction in transmittance in the spectral range from 400 nm to 500 nm. The region with the superlattice is arranged outside the central field of vision of the composite pane such that the reduction in transmittance has no negative effects for the occupants of the vehicle, in particular in terms of the total transmittance and any color cast.

When functional films are used in composite panes, the person skilled in the art must take into account a wide variety of requirements when designing the coatings, in particular in vehicle construction. The transmittance in the visible spectral range is reduced by the typically metal-containing conductive layers of the functional films. A greater amount of conductive material for the individual layers can also result in a reduction in the transparency of the composite pane. Since, for example, a windshield must satisfy strict requirements for minimum transparency (at least 70% transmittance in the visible spectral range in accordance with Regulation 43 of the United Nations Economic Commission for Europe (ECE R 43)), there are limits to the amount of conductive material and the number of layers for the functional films.

Furthermore, in addition to transparency, the reflection spectrum of the composite pane and other boundary conditions must be taken into account. This concerns in particular the color effect of the composite pane, because generally only panes with green-blue coloration are desirable, but not a yellow or red coloration (based on the reflection color).

Usually, the higher the number of conductive layers, the better the coating can be optimized in terms of a desired level of transmittance, coloration, or a desired sheet resistance. However, coatings as functional films, in particular with a plurality of noble metal layers, are, on the one hand, comparatively cost-intensive and also limited in their adjustability to the desired color impression in combination with the required transparency. Consequently, alternatives are sought for optimizing the color effect of a composite pane that is to be designed with one or a plurality of functional films.

The object of the present invention is, consequently, to provide a transparent composite pane having at least one functional film, whereby, simultaneously with the function provided by this film, an improved aesthetic appearance, in particular, as free as possible from undesirable color tones in reflection, can be achieved.

The object of the present invention is accomplished according to the invention by a composite pane in accordance with claim 1. Preferred embodiments are apparent from the subclaims.

According to the invention, a composite pane is provided, comprising an outer pane and an inner pane joined to one another via a thermoplastic intermediate layer, wherein the composite pane has at least one functional film that contains at least one metal layer, in particular a transparent metal layer, and the thermoplastic intermediate layer is formed with at least one thermoplastic film that contains refractive-index-reducing agents and by means of these refractive-index-reducing agents, the refractive index of the thermoplastic film is reduced by at least 0.05 (n Δ−0.05) in the optically visible range between 380 nm and 780 nm.

In other words, according to the invention, the intermediate layer of the composite pane is formed from at least one thermoplastic film, whose refractive index is reduced by at least 0.05 (n Δ−0.05) by refractive-index-reducing agents compared to the refractive index n of a thermoplastic film having a comparable composition, but without the refractive-index-reducing agents used according to the invention. At the same time, the other properties, for example, optical or mechanical properties, of the films and of the resulting composite pane, such as the required transparency, light transmittance, breaking strength/pummel value, or processability, are essentially retained. Surprisingly, the composite pane according to the invention has, as a result, an improved color impression in reflection without other properties of the composite pane being negatively affected.

The composite pane according to the invention comprises an outer pane and an inner pane that are joined to one another via a thermoplastic intermediate layer. The composite pane is intended, in a window opening, in particular the window opening of a vehicle, to separate the interior from the external surroundings. In the context of the invention, the term “inner pane” refers to the pane of the composite pane facing the interior (in particular vehicle interior). The term “outer pane” refers to the pane facing the external surroundings. The composite pane is preferably a motor vehicle windshield (in particular the windshield of a motor vehicle, for example, a passenger car or a truck), a side window, or a roof panel.

The composite pane has, as a windshield, an upper edge and a lower edge as well as two side edges extending therebetween. “Upper edge” refers to that edge that is intended to point upward in the installed position. “Lower edge” refers to that edge that is intended to point downward in the installed position. The upper edge is also often referred to as the “roof edge”; and the lower edge as the “engine edge”. The outer pane and the inner pane have in each case an exterior-side surface and an interior-side surface and a peripheral side edge extending therebetween. In the context of the invention, “exterior-side surface” refers to that primary surface that is intended, in the installed position, to face the external surroundings. In the context of the invention, “interior-side surface” refers to that primary surface that is intended, in the installed position, to face the interior. The interior-side surface of the outer pane and the exterior-side surface of the inner pane face each other and are joined to one another by the thermoplastic intermediate layer.

The surfaces of the panes are typically referred to as follows: The outer side of the outer pane wird is side I. The inner side of the outer pane is side II. The outer side of the inner pane is side III. The inner side of the inner pane is side IV.

The outer pane and the inner pane are preferably formed, independently of one another, from glass or plastic, preferably soda lime glass, alkali aluminosilicate glass, polycarbonate, or polymethyl methacrylate. In a particularly preferred embodiment, the outer pane and the inner pane are made of glass.

The outer pane and the inner pane are preferably not mechanically toughened, but in other embodiments, they can be thermally toughened or partially toughened or chemically toughened.

Suitable glass panes include glass panes that are known under the tradenames Planiclear® and Planilux® (clear glass, in each case), VG 10, VG 20, VG 40, or TSANx, TSA3+, TSA4+ from Saint Gobain, with the glasses from the VG series gray-colored glasses and those of the TSA series green-colored glasses.

The outer and/or the inner pane preferably have, independently of one another, a thickness of 0.1 to 4 mm, preferably of 1 to 4 mm, particularly preferably of 1.6 mm to approx. 2.1 mm auf.

The composite pane according to the invention also has at least one functional film, preferably a transparent functional film that contains at least one metal layer. According to the invention, this functional film thus contains at least one metal or one metal alloy, for example, silver, aluminum, copper, palladium, platinum, or gold and is preferably formed on the basis of the metal or the metal alloy, i.e., consists essentially of the metal or the metal alloy apart from any dopants or impurities.

The functional film is applied, for example, on the exterior-side surface of the inner pane (side III) facing the intermediate layer or on the interior-side surface of the outer pane (side II) facing the intermediate layer. The functional film can alternatively be arranged as a coating within the intermediate layer. For this purpose, the functional film can also be applied on a carrier film, for example, made of polyethylene terephthalate (PET) with a thickness of approx. 20 μm to 100 μm, for example, 50 μm, which is arranged for example between two plies of thermoplastic material, for example, between two polymer films, for example, PVB films.

A “transparent functional film” is understood to be a layer or a layer system (coating) that has average transmittance in the visible spectral range of at least 70%, preferably at least 75%, i.e., that does not substantially restrict through-vision through the pane while providing or enabling functions such as reflection for an HUD display, IR ray reflection for a solar shading coating. The functional film can also be designed as a heatable coating that is contacted electrically and heats up when current flows through it. The transmittance in the visible spectral range is determined in accordance with the method specified by ECE-R 43, Annex 3, § 9.1 for testing the light permeability of motor vehicle windows.

In another embodiment of the composite pane according to the invention, the functional film, as a transparent metal layer includes at least one silver layer, one aluminum layer, copper layer, palladium layer, platinum layer, or a gold layer. According to the invention, the at least one metal layer is preferably a silver layer. Silver has become established as a preferred metal for the metallic layer since it both has a relatively neutral color effect and, for example, selectively reflects infrared radiation outside the visible range of solar radiation when used for sun shading.

In another preferred embodiment of the composite pane, the functional film has two to four metal layers, preferably 2, 3, or 4 silver layers. For example, layer systems with two silver functional layers, but also three or four silver functional layers for sun shading layers are used since their efficiency, i.e., the reflection of the infrared radiation outside the visible range in relation to the transmittance of visible radiation is greater. In addition, the adjustability of certain properties, such as the color effect, is also more variable with a greater number of layers.

The metallic layers (metal layers), preferably silver layers, are usually embedded between dielectric layers in the functional films. In other words, the metal layers are sandwiched between dielectric layers.

The dielectric layers of the functional film can include suitable materials known to the person skilled in the art, for example, at least one metal oxide such as ZnO, ZnSnOx, or a metal nitride, such as Si₃N₄ or SiZrNx or NiCr. The dielectric materials can also have dopants, such as aluminum.

Each metal layer, for example, silver layer, is preferably arranged between two dielectric layers. The metal layers and the dielectric layers are arranged such that, for example, at least one dielectric layer, preferably two or more dielectric layers, are arranged in each case between two adjacent silver layers, between which no other silver layer is arranged, and that at least one other dielectric layer is arranged above the uppermost metal layer, which faces the outer pane in the installed position; and that at least one other dielectric layer is arranged below the lowest metal layer, which faces the inner pane. According to the invention, the dielectric layers preferably have a thickness of 0.1 nm to 100 nm, particularly preferably of 0.2 nm to 50 nm, for example, between 0.3 nm and 45 nm.

The functional film according to the invention can, for example, be applied as a coating by physical vapor deposition (PVD) by cathodic sputtering (“sputtering”), most particularly preferably by magnetron-enhanced cathodic sputtering, for example, on the inner pane. The functional films are preferably applied as coatings on the panes prior to lamination. Instead of applying the coating to a pane surface, it can, in principle, also be provided on a carrier film arranged in the intermediate layer. This can be accomplished, for example, in that during production of the composite pane, the functional film is positioned between at least two thermoplastic polymer films and then the polymer films are fused to one another through the action of heat, for example, during the lamination and the IR-radiation-reflecting film is flowed around and, as it were, enclosed by the thermoplastic material of the films. This protects the functional film against environmental influences.

In another embodiment of the composite pane, the refractive index of the thermoplastic film is reduced between 0.05 and 0.15 in the optically visible range (380 nm-780 nm) by the refractive-index-reducing agents contained therein. According to the invention, by the reduction of the refractive index of the thermoplastic film, an improved aesthetic appearance of the composite pane, in particular as free as possible from unwanted color tones in reflection, can be achieved. It has been shown that with greater reduction of the refractive index of the thermoplastic film, the color effect can even be influenced more strongly toward the desired color neutrality, or toward reduction or avoidance of undesirable yellow and red tones in the composite pane.

In a preferred embodiment of the invention, the refractive-index-reducing agents are nanoparticles that have, in the optically visible range, a refractive index <1.4, preferably <1.3 at a wavelength of 550 nm. I.e., the values indicated for the refractive index are measured at a wavelength of 550 nm. The refractive index can, for example, be determined by means of ellipsometry. Ellipsometers are commercially available.

In another preferred embodiment, provision is made for the refractive-index-reducing agents to be, contain, or comprise metal fluoride nanoparticles, in particular MgF₂, CaF₂, or hollow SiO₂ nanoparticles. Alkali metal fluorides, with a refractive index <1.4 and methods for producing alkali metal fluorides, for example, the aforementioned MgF₂ and CaF₂, are described, for example, in K. Scheurell, Inorganics 6,128, 2018. The alternatively mentioned hollow SiO₂ nanoparticles are disclosed, for example, in M. Gorsd, Procedia Materials Science 8, 567-576, 2015 and in T. Gao, Appl. Phys. A 110, 65-70, 2013.

In another embodiment according to the invention, the thermoplastic film contains at least 1 wt.-% of refractive-index-reducing agents, in particular nanoparticles, based on the total weight of the film in the volume of the thermoplastic film. Preferably, the thermoplastic film contains 0.5 to 50 wt.-%; preferably 1 to 25 wt.-%, 1 to 0 wt.-%, for example, as much as 5 wt.-% of refractive-index-reducing agents, in particular nanoparticles, based on the total weight of the film in the volume of the thermoplastic film.

According to the invention, the refractive-index-reducing agents are preferably nanoparticles with an average diameter of 5 nm to 200 nm. Particles have an average particle diameter of 5 nm to 200 nm, preferably of <150 nm, particularly preferably <100 nm, for example, <90 nm, <80 nm, <70 nm, or <50 nm. Preferably, the particle size distribution is as homogenous as possible i.e., the particles used have as nearly as possible the same diameter. In the context of the invention, particles with an average diameter less than or equal to 500 nm are referred to as nanoparticles. Nanoparticles sizes can be measured using dynamic light scattering (DLS).

In another embodiment of the composite pane according to the invention, the thermoplastic film is a polyvinyl butyral (PVB) film, an ethylene vinyl acetate (EVA) film, or a polyurethane (PU) film, preferably a PVB film. In other words, the thermoplastic films according to the invention are designed as thermoplastic polymer films that contain polyvinyl butyral (PVB), ethylene vinyl acetate (EVA), or polyurethane, and/or mixtures and/or copolymers thereof. Polyvinyl butyral is particularly preferred. The thermoplastic films are preferably formed on the basis of the materials mentioned, but can contain other components, for example, plasticizers. The polymer film types mentioned are well suited, in particular, for the automotive sector.

Advantageously, it is possible to incorporate the refractive-index-reducing agents, in particular nanoscale particles, into such polymer films without negatively affecting the other properties, for example, mechanical properties, of the films. The thermoplastic films can be standard films with a refractive index lowered according to the invention by at least 0.05 in the optically visible range between 380 nm and 780 nm by the refractive-index-reducing agents. The thermoplastic films can be clear, colored/tinted (for example, in the case of a roof panel), with a colored band, but also with other special properties or functions, either individually or in combination. The thermoplastic films can, for example, be wedge films for the function as a projection surface for a head-up display or acoustic films.

Preferably, the thermoplastic film of the composite pane according to the invention has a thickness of at least 0.1 mm to a maximum of 2 mm, preferably 0.2 mm to 1 mm, particularly preferably 0.3 mm to 0.8 mm. Polymer films of the intermediate layer, in particular the PVB films, have, for example, a thickness of 0.38 mm, 0.76 mm, or 0.81 mm. Other properties of the composite glass pane can be influenced by the thickness of the films. For example, thicker PVB films result in improved sound damping, in particular when they contain an acoustically effective core, increased burglary resistance of the composite glass pane, and also increased protection against ultraviolet radiation (UV protection).

In another preferred embodiment of the composite pane, provision is made for the intermediate layer to be formed from two or more thermoplastic films having a refractive index different from one another. The optical properties, in particular the color effect in reflection from the outer and the inner side can thus be further advantageously influenced and optimized to the desired values for the composite pane.

The invention further includes a method for producing a composite pane according to the invention as described in various embodiments above, comprising an outer pane and an inner pane joined to one another via a thermoplastic intermediate layer, wherein the composite pane has at least one functional film that contains at least one transparent metal layer, and the thermoplastic intermediate layer is formed with at least one thermoplastic film that contains refractive-index-reducing agents, and by means of these refractive-index-reducing agents, the refractive index of the thermoplastic film is reduced by at least 0.05 in the visible range, comprising the steps:
S1: Providing a thermoplastic film containing refractive-index-reducing agents;
S2: Providing a functional film on the outer pane, the inner pane, the thermoplastic film, and/or on a carrier film;
S3: Forming a stack sequence from the outer pane, the inner pane, and the thermoplastic film, optionally, the carrier film with a functional film;
S4: Bonding the stack sequence under the action of pressure, heat, and/or vacuum.

In step 1, the thermoplastic films can be produced by methods known per se. In a preferred embodiment, the films are fabricated with the refractive-index-reducing nanoparticles having a refractive index <1.4, preferably <1.3 in the optically visible 30 range. In other words, the nanoparticles are dispersed in the volume of the films. The production of the films with the nanoparticles dispersed therein can be done, for example, in a manner analogous to the processes described in JP 2002326846 A, US2003/0054160 A1, or EP1227070 B1.

Advantageously, it is possible to incorporate the refractive-index-reducing agents, in particular nanoscale particles, into such polymer films without negatively affecting the other properties, for example, mechanical properties, of the films. The thermoplastic films can be standard films, for example, PVB films supplemented by the refractive-index-reducing agents according to the invention, which reduce the refractive index of the film by at least 0.05 in the optically visible range (380 nm to 780 nm). The thermoplastic films can be clear, colored/tinted, with a colored band, but also with other special properties or functions, either individually or in combination. The thermoplastic films can, for example, be wedge films for the function as a projection surface for a head-up display or acoustic films.

In another preferred embodiment, provision is made for the refractive-index-reducing agents to be, contain, or comprise metal fluoride nanoparticles, in particular MgF₂, CaF₂, or hollow SiO₂ nanoparticles.

In step S2, the functional film can be applied, for example, by physical vapor deposition (PVD), by cathodic sputtering (sputtering), or by magnetron-enhanced cathodic sputtering on the inner pane or the outer pane. Preferably, the functional films are applied on the inner side II of the outer pane or the outer side III of the inner pane. The coatings are preferably applied on the panes prior to lamination.

Preferably, at least 80% of the pane surface is provided with the functional film as a coating. In particular, the composite pane is provided with the coating over its entire surface with the exception of a circumferential edge region and, optionally, a local region that are intended, as communications, sensor, or camera windows, to ensure the transmittance of electromagnetic radiation through the composite pane and, consequently, are not provided with the coating. The circumferential uncoated edge region can have, for example, a width of up to 20 cm. This prevents direct contact of the coating with the surrounding atmosphere such that the coating is advantageously protected, in the interior of the composite pane, against corrosion and damage.

Instead of applying the functional films as a coating on a pane surface, it can, in principle, also be provided on a carrier film, for example, made of polyethylene terephthalate (PET), which is arranged in the intermediate layer. This can be achieved, for example, by positioning the functional film between at least two thermoplastic polymer films, in step S3 of the composite pane production.

In step S3: the outer pane, the inner pane, and the thermoplastic film, optionally, the carrier film with a functional film are arranged flat atop one another in the usual manner.

If the composite pane is to be curved, the outer pane and the inner pane are preferably preferably subjected, before step S4 and preferably after any coating processes in step S2, to a bending process. Preferably, the outer pane and the inner pane are bent together congruently (i.e., at the same time and using the same tool), since as a result, the shape of the panes is optimally matched for the subsequent lamination. Typical temperatures for glass bending processes are, for example, 500° C. to 700° C.

The joining of the outer pane and the inner pane via the thermoplastic intermediate layer from the stack sequence to form the composite pane in step S4 is preferably done by lamination under the action of heat, vacuum, and/or pressure. Methods known per se for producing a composite pane can be used. During lamination, the heated, flowable thermoplastic material flows around the functional film such that a stable bond is established and the sun shading coating is encapsulated in the intermediate layer and protected against damage and environmental influences.

For example, so-called autoclave methods can be carried out at an elevated pressure of approx. 10 bar to 15 bar and temperatures of 130° C. to 145° C. for about 2 hours. Vacuum bag or vacuum ring methods known per se operate, for example, at about 200 mbar and 80° C. to 110° C. The outer pane, the thermoplastic intermediate layer, and the inner pane can also be pressed in a calender between at least one roller pair to form a pane. Systems of this type are known for producing panes and usually have at least one heating tunnel upstream from a pressing unit. The temperature during the pressing operation ranges, for example, from 40° C. to 150° C. Combinations of calendering and autoclaving methods have proved particularly effective in practice. Alternatively, vacuum laminators can be used. These consist of one or more heatable and evacuable chambers in which the panes are laminated within, for example, about 60 minutes at reduced pressures of 0.01 mbar to 800 mbar and temperatures from 80° C. to 170° C.

In a preferred embodiment of the method, provision is made for the thermoplastic film (4B) provided in step S1 to be formed with metal fluoride nanoparticles, in particular MgF₂, CaF₂, or with hollow SiO₂ nanoparticles as refractive-index-reducing agents. Nanoparticles can be integrated into the films using conventional methods without other properties being adversely affected.

In another embodiment of the method, provision is made in step S1 for two or more thermoplastic films (4B, 4, 4A) having a different refractive index to be used. In other words, an intermediate layer is formed from two or more thermoplastic films having a different refractive index from one another. The optical properties, in particular, the color effect in reflection from the outside and the inside of the composite pane can thus be advantageously influenced again and optimized to the desired values for the composite pane.

The invention further includes the use of the composite pane according to the invention in means of locomotion for travel on land, in the air, or on water, in particular in motor vehicles, for example, as a windshield, rear window, side window, and/or a roof panel.

All standards mentioned refer to the version valid on the filing date.

The various embodiments of the invention can be implemented individually or in any combinations. In particular, the features mentioned above and to be explained in the following can be used not only in the combinations indicated, but also in other combinations or in isolation, without departing from the scope of the invention, unless exemplary embodiments and/or their features are explicitly mentioned only as alternatives or are mutually exclusive.

In the following, the invention is presented in more detail with reference to the examples and figures. It should be noted that different aspects are described, each of which can be used individually or in combination. In other words, any aspects can be used with different embodiments of the invention unless explicitly presented as a pure alternative.

The drawings are simplified schematic representations and are not to scale. The drawings in no way restrict the invention.

### EXAMPLES

TABLE 1

| ClimaCoat ® | Standard | PVB2 | PVB3 with |
|---|---|---|---|
| with 4 Silver | PVB1 | with Low | Ultralow |
| Layers | Refractive | Refractive Index | Refractive |
| Laminate | Index 1.48 | (Δ −0.05) | Index (Δ −0.13) |
| TL (A) | 71.7% | 71.6% | 71.4% |
| a* 8° | −7.6 | −7.7 | −7.7 |
| b* 8° | −10.7 | −9.4 | −7.8 |
| a* 60° | +0.9 | −0.2 | −1.4 |
| b* 60° | −5.3 | −4.3 | −3.2 |

Table 1 compares the integral values for a composite pane with a sheet resistance of approx. 0.7 ohms, with a standard PVB, available from Saint Gobain under the tradename ClimaCoat®, to the values of identically constructed and comparable composite pane laminates, but once with a low refractive index (reduced by 0.05 compared to the standard PVB) and a PVB with an ultralow refractive index (reduced by 0.13 compared to the standard PVB). The reflection values are determined by simulations with a standard optical simulation program.

The specified color values describe the reflection color of the respective composite pane and are based on the L*a*b*color space (also: Lab color space), which is standardized in EN ISO 11664-4 “Colorimetry—Part 4: CIE 1976 L*a*b*Color space” and the more recent DIN EN 410. The specified color values a*, b* refer at least to the exterior-side reflection color when irradiated by the light source D65 and irradiation angles of 8° and 60° (angle relative to the surface normal), measured with irradiation of the outer pane with radiation of mixed polarization (50% s, 50% p) and measurement condition that are specified in said standards specified with D65/10.

It can be seen that with the increasing reduction of the refractive index, the external reflection is less blue at 8° and is less red at 60°. The difference compared to the color values of the composite pane with the standard PVB film is in each case more than one point and can therefore be regarded as a significant improvement. The recognizable tendency toward color neutrality with the reduction of the refractive index of the PVB film makes possible the assumption that a further drop in the refractive index of the PVB film used could further strengthen this effect of the improved color effect in reflection of the composite pane.

TABLE 1-1
Layer structure for the composite panes of Table 1 having 4 metal layers

| | Composite pane with | |
|---|---|---|
| | functional film with | |
| | 4 silver layers | Layer thickness |
| Outer pane 1 | Clear glass pane | 2.1 mm |
| | Planiclear ® PLC | |
| Thermoplastic film 4 | Standard PVB1 4A | 0.737 mm |
| | (prior art) | |
| | or | |
| | PVB2 with reduced | |
| | refractive index n(Δ −0.05) | |
| | 4B (according to the | |
| | invention) | |
| | or | |
| Thermoplastic film 4 | PVB3 with reduced | |
| | refractive index n(Δ −0.13) | |
| | 4B (according to the | |
| | invention) | |
| Functional film 5 | Si₃N₄ | 15.8 nm |
| | SiZrNx | 8.1 nm |
| | ZnO | 13 nm |
| | NiCr | 0.2 nm |
| | Ag [metal layer 6] | 10.9 nm |
| | ZnO | 12.0 nm |
| | ZnSnOx | 10.0 nm |
| | SiZrNx | 21.1 nm |
| | Si₃N₄ | 20.9 nm |
| | ZnO | 16.0 nm |
| | NiCr | 0.2 nm |
| | Ag [metal layer 6] | 14.2 nm |
| | ZnO | 14.0 nm |
| | ZnSnOx | 11.0 nm |
| | SiZrNx | 18.4 nm |
| | Si₃N₄ | 17.2 nm |
| | ZnO | 15.0 nm |
| | NiCr | 0.3 nm |
| | Ag [metal layer 6] | 13.5 nm |
| | ZnO | 16.0 nm |
| | ZnSnOx | 10.0 nm |
| | SiZrNx | 35.5 nm |
| | ZnO | 16 nm |
| | NiCr | 0.2 nm |
| | Ag [metal layer 6] | 11.5 nm |
| | ZnO | 11.0 nm |
| | ZnSnOx | 8.0 nm |
| | SiZrNx | 13.7 nm |
| Inner pane 2 | Clear glass pane | 1.6 mm |
| | Planiclear ® PLC | |

Table 1-1 shows the layer structures for the three composite panes having four silver layers, the values of which were determined by simulation, retaining the layer sequence and the layer thicknesses in each case, and the difference in each case being only in the different refractive index of the PVB1 (standard/reference n at 500 nm 1.48) and of the PVB2 (n(Δ−0.05) and of the PVB3 (n(Δ−0.13) used for the composite pane.

TABLE 2

| ClimaCoat ® with 3 | | PVB2. With Reduced |
|---|---|---|
| Silver Layers | | Refractive Index |
| Laminate | Standard PVB1 | (n Δ −0.05) |
| TL (A) | 72.4% | 72.7% |
| a* 8° | −2.5 | −1.3 |
| b* 8° | −2.9 | −3,1 |
| a* 60° | +0.1 | −0.2 |
| b* 60° | 5.0 | 5.0 |

Table 2 compares the integral values for a composite pane with a sheet resistance of approx. 0.9 ohms, with a standard PVB, available from Saint Gobain under the tradename ClimaCoat®, to identically structured and comparable composite pane laminates, but once with a PVB with a low refractive index (reduced by 0.05 compared to the standard PVB). The simulation shows the same tendencies in the reflection values as in the simulation measurements shown in Table 1, but less pronounced.

TABLE 2-1
Layer structure for the composite panes of Table 2

| | Composite pane with | |
|---|---|---|
| | functional film with 3 silver | |
| | layers | Layer thickness |
| Outer pane 1 | Clear glass pane | 2.1 mm |
| | Planiclear® PLC | |
| Thermoplastic film 4 | Standard PVB1 4A | |
| | (prior art) | |
| | or | |
| | PVB2 with reduced | 0.76 mm |
| | refractive index n (Δ −0.05) | |
| | 4B (according to the | |
| | invention) | |
| Functional film 5 | SiZrNx | 9.6 nm |
| | Si₃N₄ | 9.9 nm |
| | ZnO | 13 nm |
| | NiCr | 0.2 nm |
| | Ag [metal layer 6] | 9.0 nm |
| | ZnO | 14.0 nm |
| | ZnSnOx | 7.0 nm |
| | SiZrNx | 21.5 nm |
| | Si₃N₄ | 25.5 nm |
| Functional film 5 | ZnO | 10.0 nm |
| | NiCr | 0.3 nm |
| | Ag [metal layer 6] | 9.5 nm |
| | ZnO | 9,0 nm |
| | ZnSnOx | 8.0 nm |
| | SiZrNx | 42.1 nm |
| | ZnO | 13 nm |
| | NiCr | 0.2 nm |
| | Ag [metal layer 6] | 9.5 nm |
| | ZnO | 13 nm |
| | ZnSnOx | 7.0 nm |
| | SiZrNx | 10.9 nm |
| Inner pane 2 | Clear glass pane | 1.6 mm |
| | Planiclear ® PLC | |

Table 2-1 shows the layer structures for the two composite panes having three silver layers, wherein the layer sequence and the layer thicknesses are retained, and the difference in each case being only in the different refractive index of the PVB1 (standard/reference n at 500 nm 1.48) and of the PVB2 (n(Δ−0.05) used for the composite pane.

TABLE 3
Layer structure of the HUD composite pane laminate

| HUD composite | Standard PVB1 | PVB2 with reduced |
|---|---|---|
| pane | refractive index n | refractive |
| laminate | 1.48 at 500 nm | index (Δ −0.05) |
| TL (A) | 71.9% | 71.5% |
| a*t | −1.5 | −1.3 |
| b*t | 0.6 | 0.9 |
| RL(A) | 22.9 | 23.4 |
| a* 8° | −0.5 | −1.1 |
| b* 8° | 1.8 | 1.0 |
| RL(A) 60° | 28.0 | 28.1 |
| a* 60° | −0.6 | −1.1 |
| b* 60° | 1.1 | 0.5 |
| RL(A) p-pol | 20.1 | 20.1 |
| a* p-pol | 0.6 | 0.4 |
| b* p-pol | 1.1 | 0.3 |
| TTS | 59.7 | 59.7 |
| Polarization ratio | 1.405 | 1.412 |

Table 3 compares the integral values for an HUD-compatible composite pane (HUD composite pane) with a silver layer (with a standard PVB (PVB1) to an identically structured and comparable composite pane laminate, but with a PVB with a low refractive index n. PVB2 compared to PVB1: n is reduced by 0.05 (n Δ−0.05).

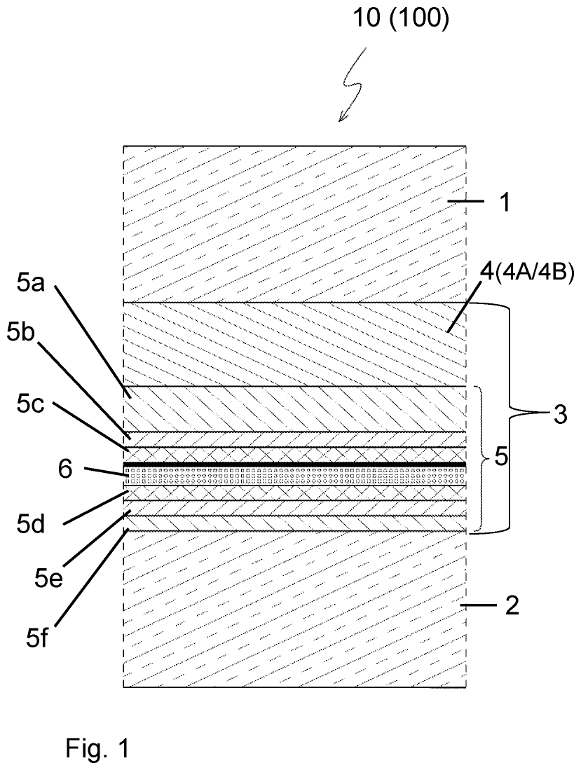

The layer structure for the composite pane laminates which was examined with the simulation with an optical simulation program is shown in FIG. 1 and the associated description.

This simulation also shows, with almost constant light transmittance TL(A) and an identical TTS value (total transmittance of solar energy), a significant effect in the color effect of the composite pane in reflection. The reflection color at 8° and 60° is shifted into the green range by the PVB film with the reduced refractive index. The HUD p-pol reflection color also becomes more color-neutral with the PVB with the reduced refractive index. This means that, in the case of an HUD projection, a disruptive color shift can be reduced or avoided. The closer the color values a* and b* come to zero, the more color-neutral the color effect in reflection. Surprisingly, in the comparison of the two HUD composite pane laminates using the PVB with the reduced refractive index, a polarization ratio (p-polarization/s-polarization) increased by 0.007 was additionally found. This ratio should be as high as possible for the functionality of camera systems integrated into the windshield.

The value shown in Tables 1 to 3 were obtained by simulation with an optical simulation program.

### DEFINITIONS

RL(A) visible external reflection [%]. External reflectance describes the reflected portion of the visible radiation incident from the external environment.
TL(A) visible light transmittance [%] of the composite panes
TTS total transmitted thermal radiation [%]
RL(A) 60° visible reflection at a viewing angle of 60 [%]
RL(A) p-pol visible p-pol reflection [%]
L*, a*, b* Color Coordinates (Color Space CIE, International Commision on Illumination)

The values for light transmittance (TL) and reflection (RL) are based on illuminant A, i.e., the visible portion of sunlight at a wavelength of 380 nm to 780 nm.

The figures depict:

FIG. 1 a schematic cross-section through a layer structure for a composite pane according to the invention using the example of an HUD-compatible composite pane laminate (HUD composite pane/HUD laminate);

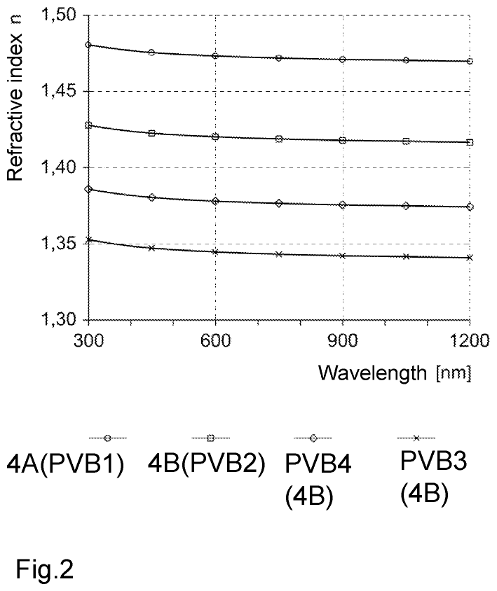

FIG. 2 a diagram of the refractive index n and wavelength for PVB films having a differently reduced refractive index

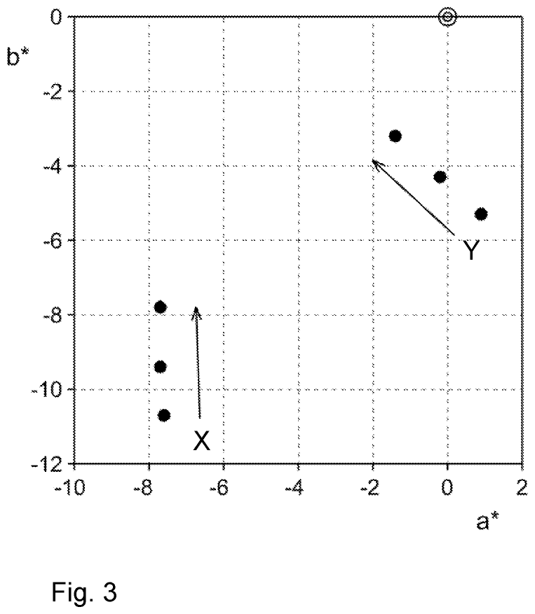

FIG. 3 the color values a*b* of the composite panes of Table 1 with the thermoplastic films PVB1, PVB 2, and PVB 3 in a color diagram.

FIG. 1 depicts a schematic cross-section through a layer structure 10 for a composite pane 100 according to the invention using the example of an HUD laminate, as examined with the optical simulation program. The values for the comparative optically simulated measurements, once for a composite pane 100 with a clear standard PVB film 4A (prior art) and once with a clear PVB film 4B with a refractive index n reduced according to the invention are shown in Table 3. The layer structure 10 for the composite pane 100 comprises an outer pane 1, an inner pane 2, and an intermediate layer 3. The inner pane 2 and the outer pane 1 are, in the example used as the basis of the optical simulation (Table 3), 2.1-mm-thick clear glass panes, available, for example, under the tradename Planiclear®. The intermediate layer 3 comprises a thermoplastic film 4 (4A prior art/4B with refractive index n reduced according to the invention) in the comparative examples of Table 3 in each case a PVB film 4A (PVB1 standard/prior art) and PVB film 4B (PVB2/with reduced refractive index) with a thickness of 0.76 mm. On the outer side III of the inner pane 2 facing the thermoplastic film 4 (4A/4B), a multilayer functional film 5 with a transparent silver layer 6 is arranged in the intermediate layer 3. The functional film 5 of the example composite panes 100 comprises a silver layer 6 with a thickness of 12.5 nm and further dielectric layers (5a, 5b, 5c, 5d, 5e, 5f). The layer structure for the optical simulations of Table 3 is shown in detail in Table 4. The functional film 5 can be applied to the inner pane, for example, by conventional methods, such as sputtering. It has been shown that the composite panes 100 according to the invention present, with virtually identical transmittance values TL(A), a significant, positive effect in the color effect in reflection. The reflection color of the composite pane 100 is shifted into the green range by the PVB film 4B according to the invention (Table 3, PVB2) with the reduced refractive index n. Also, the HUD p-pol reflection color becomes more color-neutral with the PVB film 4B (PVB2) with a reduced refractive index n. This means that with the composite pane 100 manufactured according to the invention with the PVB film 4B with the reduced refractive index n, a disruptive color shift in an HUD projection can be reduced or avoided in comparison with the prior art (use of the standard PVB film 4A). The closer the color values a* and b* come to zero, the more color-neutral the color effect in reflection. In addition, surprisingly, in the comparison of the two HUD composite pane laminates 100 using the PVB2 4B with the reduced refractive index, a polarization ratio (p-polarization) increased by 0.007 was found.

TABLE 4
Structure of a composite pane 100 using the example of an HUD
composite pane with a silver layer compared to a PVB1 (4A)
and a PVB2 (4B) as a thermoplastic film 4 (4A/4B)

| | HUD Composite pane | Layer thickness |
|---|---|---|
| Outer pane 1 | Clear glass pane | 2.1 mm |
| | Planiclear ® PLC | |
| Thermoplastic film 4 | Standard PVB1 4A | 0.76 mm |
| | (prior art) | |
| | or | |
| | PVB2 with reduced | |
| | refractive index 4B | |
| | (according to the invention) | |
| | Si₃N₄ | 50 nm |
| Functional film 5 | SiZrNx | 10 nm |
| | ZnO | 10 nm |
| | NiCr | 0.3 nm |
| | Ag [metal layer 6] | 12.5 nm |
| | ZnO | 10.0 nm |
| | SiZrNx | 10.0 nm |
| | Si₃N₄ | 10.0 nm |
| Inner pane 2 | Clear glass pane | 2.1 mm |
| | Planiclear ® PLC | |

FIG. 2 depicts a diagram of the refractive index n and wavelength for four PVB films with a differently reduced refractive index. The simulations that yielded the values shown in Table 1 to 3 were performed with PVB1 (standard/reference/refractive index at 500 nm approx. 1.48), PVB 2 (refractive index at 500 nm approx. 1.43; Δ−0.05), and PVB 3 (refractive index at 500 nm approx. 1.35; Δ−0.13). With PVB 4, an additional PVB film with a refractive index at 500 nm, of approx. 1.39 is graphically depicted.

FIG. 3 depicts the color values a* and b* determined with the optical simulation program for the composite panes 100 of Table 1 with the different thermoplastic films PVB1 (standard/reference), PVB 2 (refractive index Δ−0.05), and PVB 3 (refractive index at 500 nm n Δ−0.13) in a color coordinate diagram.

It can be seen that with the increasing reduction of the refractive index, the external reflection is less blue at 8° and less red at 60°. The tendencies toward color neutrality with the reduction of the refractive index of the PVB film 4 represented by the arrows X (value of reflection at 8°) and Y (value of reflection at 60°) make possible the assumption that a further drop in the refractive index n of the PVB film used could further strengthen this effect of the improved color effect in reflection of the composite pane 100.

The composite pane according to the invention surprisingly exhibits good optical and aesthetic properties, whereby, in particular, undesirable color tones in reflection of the composite pane can be minimized or even avoided.

This is possible according to the invention without the other properties of the composite pane being negatively affected.

According to the invention, composite panes with an improved color impression in reflection are thus provided. Advantageously, the improved color effect and the aesthetic visual effect improved thereby can be achieved without other properties of the composite pane being negatively affected.

### LIST OF REFERENCE CHARACTERS

100 composite pane
10 layer structure
1 outer pane
2 inner pane
3 intermediate layer
4 thermoplastic film
4A standard PVB film (prior art)
4B PVB film 4B (PVB2/with refractive index reduced according to the invention).
5 functional film
5a, 5b, 5c, 5d, 5e, 5f dielectric layers
6 metal layer
I outer surface of the outer pane 1
II inner surface of the outer pane 1
III outer surface of the inner pane 2
IV inner surface of the inner pane 2
X tendency values of reflection at 8° with decreasing refractive index of the PVB
Y tendency values of reflection at 60° with decreasing refractive index of the PVB

1. A composite pane comprising an outer pane and an inner pane that are joined to one another via a thermoplastic intermediate layer, and at least one functional film that contains at least one metal layer, and the thermoplastic intermediate layer is formed with at least one thermoplastic film that contains refractive-index-reducing agents and said refractive-index-reducing agents reduce the refractive index of the thermoplastic film by at least 0.05 in the optically visible range between 380 nm and 780 nm.

2. The composite pane according to claim 1, wherein the functional film includes at least one silver layer, aluminum layer, copper layer, palladium layer, platinum layer, or gold layer as the metal layer.

3. The composite pane according to claim 1, wherein the functional film has two to four metal layers.

4. The composite pane according to claim 1, wherein the functional film includes at least two dielectric layers sandwiching the metal layer.

5. The composite pane according to claim 1, wherein the refractive index of the thermoplastic film is reduced between 0.05 and 0.15 in the optically visible range by the refractive-index-reducing agents contained therein.

6. The composite pane according to claim 1, wherein the refractive-index-reducing agents are nanoparticles having a refractive index n<1.4 in the optically visible range.

7. The composite pane according to claim 1, wherein the refractive-index-reducing agents are, contain, or comprise metal fluoride nanoparticles, or hollow SiO₂ nanoparticles.

8. The composite pane according to claim 1, wherein the thermoplastic film contains at least 1 wt.-% refractive-index-reducing agents based on the a total weight in a volume of the thermoplastic film.

9. The composite pane according to claim 1, wherein the refractive-index-reducing agents are nanoparticles with an average diameter of 5 nm to 200 nm.

10. The composite pane according to claim 1, wherein the thermoplastic film is a polyvinyl butyral (PVB) film, an ethylene vinyl acetate (EVA) film, or a polyurethane (PU) film.

11. The composite pane according to claim 1, wherein the thermoplastic film has a thickness of at least 0.1 mm to a maximum of 2 mm.

12. The composite pane according to claim 1, wherein the thermoplastic intermediate layer is formed from two or more thermoplastic films having a refractive index different from one another.

13. A method for producing a composite pane according to claim 1 comprising the outer pane and the inner pane that are joined to one another via the thermoplastic intermediate layer, and the at least one functional film that contains the at least one metal layer, and the thermoplastic intermediate layer is formed with the at least one thermoplastic film that contains refractive-index-reducing agents, and the refractive-index-reducing agents reduce the refractive index of the thermoplastic film by at least 0.05 in the visible range, comprising the steps:
S1: providing the at least one thermoplastic film containing refractive-index-reducing agents;
S2: providing the functional film on the outer pane, the inner pane, the thermoplastic film, and/or a carrier film;
S3: forming a stack sequence from the outer pane, the inner pane and the thermoplastic film, optionally the carrier film with a functional film, and
S4: bonding the stack sequence under the action of pressure, heat, and/or vacuum.

14. The method according to claim 13, wherein in step S1, the thermoplastic film contains metal fluoride nanoparticles, or hollow SiO₂ nanoparticles as refractive-index-reducing agents.

15. The method according to claim 13, wherein in step S1, two or more thermoplastic films having a different refractive index are used.

16. The composite pane according to claim 3, wherein the functional film has 2, 3, or 4 silver layers.

17. The composite pane according to claim 6, wherein the refractive-index-reducing agents are nanoparticles having a refractive index n<1.3 in the optically visible range.

18. The composite pane according to claim 7, wherein the metal fluoride nanoparticles are MgF₂ or CaF₂ nanoparticles.

19. The composite pane according to claim 8, wherein the refractive-index-reducing agents are nanoparticles.

20. The composite pane according to claim 10, wherein the thermoplastic film is a polyvinyl butyral (PVB) film.
